(19) United States
(12) Patent Application Publication
(10) Pub. No.: US 2011/0297226 A1
(43) Pub. Date: Dec. 8, 2011

(54) PHOTOVOLTAIC CELL AND ITS TRANSPARENT LIGHT CONVERSION POWDER

(76) Inventors: Chi-Ruei TSAI, Taipei City (TW); Kun-Lin Chang, Sanchong City (TW); Chen-Pei Hsu, Sanchong City (TW); Wen-Sheng Huang, Sanchong City (TW)

(21) Appl. No.: 12/898,034

(22) Filed: Oct. 5, 2010

(30) Foreign Application Priority Data
Jun. 3, 2010 (TW) 099117883

(51) Int. Cl. H01L 31/055; C09K 11/78

(52) U.S. Cl. 136/257; 252/301.4 R

(57) ABSTRACT

A photovoltaic cell is disclosed to include a monocrystalline silicon wafer, and a transparent light conversion powder which is made in the form of a polymer layer with a transparent phosphor powder filled therein and kept in contact with the outer surface of the monocrystalline silicon wafer to enhance the absorption of the short-wavelength radiation ultraviolet λ<480 nm of the sun and to re-radiate in the wavelength range λ=500˜980 nm, wherein the phosphor powder is formulated as Me^{II}O.xB₂O₃:EuCePrTbLi, in which Me^{II}=(Mg⁺²,Ca⁺²,Sr⁺²,Ba⁺²), 0.1<x<10, preferably in the range of 0.5<x<2. Furthermore, the invention also provides a transparent light conversion powder for photovoltaic cells.

### FIELD OF THE INVENTION

The present invention relates to a photovoltaic cell and its transparent light conversion powder, and in particular to a photovoltaic cell and its transparent light conversion powder which can absorb ultraviolet in the wavelength range λ<480 nm of the sun radiation and re-radiate red yellow light in the wavelength range λ=500˜980 nm to reduce the harmful effect of ultraviolet on the photovoltaic cell assembly as well as to enhance the photovoltaic cell's capability in absorbing the radiated red yellow light emitted from the transparent light conversion powder so as to increase extra current and enhance the conversion efficiency of the photovoltaic cell assembly and its transparent light conversion powder.

### BACKGROUND OF THE INVENTION

The simplest photovoltaic cell of using monocrystalline silicon to convert solar radiation into usable energy is described below. The photovoltaic cell is based on monocrystalline silicon, usually a p-type semi-conductive monocrystalline silicon wafer, which is realized by doping boron compound into a monocrystalline silicon. Gaseous antimony doped in p-type thin powder usually diffuse and form p-n junction on the silicon surface, changing the conducting species from holes into electrons, i.e. an n-type junction. The thickness of n-type deposition on silicon wafer is 0.5-3 μm. The thin powder usually connects to a metal electrode (gold or its alloy).The back of the silicon wafer is completely covered with a metal electrode or silver deposited electrode.

Furthermore, the physics principle of photovoltaic cell is described below. When the device is excited by the radiation of the sun or artificial light, the photons absorbed by silicon result in unbalanced hole-electron pairs. At this moment, the electrons in the p-layer close to the p-n junction will drift to the boundary and be attracted into the n-type junction by the electric field; on the other hand, the holes carrier (p-type carriers) in the n-type junction on the silicon wafer surface will partially drift into the silicon wafer interior, i.e. the p-type junction. This drifts results in adding extra negative charges into the n-type junction and adding extra positive charges into the p-type junction. Thus the contact potential difference of p-type junction and n-type junction reduces, leading to a voltage in the outside circuit. The semiconductor power source described above has the n-type junction as the cathode and p-type junction as the anode. The effective working efficiency of the simplest framework of the aforementioned photovoltaic cell assembly is 15 to 16%.

Taiwan patent application No. 096147526 (Publication No. 200926422) discloses a photovoltaic cell and a transparent light conversion powder, entitled “Solar cell and its transparent light conversion layer”. This patent also discloses a transparent phosphor powder formulated as (Sr₁₋ₓBaₓ)(BO₂)₂:EuLiCl, where 0 x 1.

According to this formulation, the basic structure is (BO₂⁻¹)₂ that is a combination of two units of BO₂⁻¹. When bonding with cation Ba⁺² or Sr⁺², it must be two units of BO₂⁻¹ to one Ba⁺² or Sr⁺², and the synthesized structure must have a high consistency. Therefore, this design is still not perfect.

### SUMMARY OF THE INVENTION

To overcome the aforementioned drawbacks, it the main object of the present invention to provide a photovoltaic cell and its transparent light conversion powder which can absorb ultraviolet in the short wavelength range λ<480 nm of the sun radiation and re-radiate in the wavelength range λ=500˜980 nm.

To improve the aforementioned drawback of the conventional art, it is another object of the present invention to provide a photovoltaic cell and its transparent light conversion powder, which is formulated as Me^{II}O.xB₂O₃. The basic structure of the phosphor powder is B₂O₃ and the molecule that is bonded to B₂O₃ is formulated as Me^{II}O. These two molecules are neutral molecules. The bonding of these molecules is not subject to the rule of one to one. Therefore, this chemical composition provides a high flexibility for allowing selection of the best processing conditions to achieve better conversion efficiency.

To improve the aforementioned drawback of the conventional art, it is still another object of the present invention to provide a photovoltaic cell and its transparent light conversion powder, which enhances the absorption of ultraviolet radiation.

To improve the aforementioned drawback of the conventional art, it is still another object of the present invention to provide a photovoltaic cell and its transparent light conversion powder which can radiate a spectrum covering a wide wavelength range of energy-intensity λ=500˜980 nm, not a narrow band of spectrum.

To improve the aforementioned drawback of the conventional art, it is still another object of the present invention to provide a photovoltaic cell and its transparent light conversion powder which convert 16% and over of sunlight energy into electric energy.

To achieve these and other objects of the present invention, a photovoltaic cell comprises: a monocrystalline silicon wafer, and a transparent light conversion layer which is made in the form of a polymer layer with a transparent phosphor powder filled therein and kept in contact with the outer surface of the monocrystalline silicon wafer to enhance the absorption of the short-wavelength radiation ultraviolet λ<480 nm of the sun and to re-radiate in the wavelength range λ=500˜980 nm, wherein the phosphor powder is formulated as Me^{II}O.xB₂O₃:EuCePrTbLi, in which Me^{II}=(Mg⁺²,Ca⁺²,Sr⁺²,Ba⁺²), 0.1<x<10, preferably in the range of 0.5<x<2.

To achieve these and other objects of the present invention, a photovoltaic cell comprises: a monocrystalline silicon wafer, and a transparent light conversion powder which is made by fusing a transparent phosphor powder with a glass material and bonded to the outer surface of the monocrystalline silicon wafer to enhance the absorption of a first specific wavelength range of the radiation of the sun and to re-radiate in a second specific wavelength range, wherein the phosphor powder is formulated as Me^{II}O.xB₂O₃:EuCePrTbLi, in which Me^{II}=(Mg⁺²,Ca⁺², Sr⁺²,Ba⁺²), 0.1<x<10, preferably in the range of 0.5<x<2.

To achieve these and other objects of the present invention, a photovoltaic cell comprises: a monocrystalline silicon wafer, a glass plate bonded to the outer surface of the monocrystalline silicon wafer, and a transparent thin film having filled therein a transparent phosphor powder and bonded to the back side of the glass plate and kept in contact with the outer surface of the monocrystalline silicon wafer to enhance the absorption of the short-wavelength radiation ultraviolet λ<480 nm of the sun and to re-radiate in the wavelength range λ=500˜980 nm, wherein the phosphor powder is formulated as Me^{II}O.xB₂O₃:EuCePrTbLi, in which Me^{II}=(Mg⁺²,Ca⁺²,Sr⁺²,Ba⁺²), 0.1<x<10, preferably in the range of 0.5<x<2.

To achieve these and other objects of the present invention, a transparent phosphor powder enhances the absorption of the short-wavelength radiation ultraviolet λ<480 nm of the sun and re-radiates in the wavelength range λ=500˜980 nm so as to enhance the photovoltaic cell's absorption of long-wavelength radiation for producing separated p-n electron-hole pairs, wherein the phosphor powder is formulated as Me^{II}O.xB₂O₃:EuCePrTbLi, in which Me^{II}=(Mg⁺²,Ca⁺²,Sr⁺²,Ba⁺²), 0.1<x<10, preferably in the range of 0.5<x<2.

### BRIEF DESCRIPTION OF THE DRAWINGS

The present invention can be more fully understood by reference to the following description and accompanying drawings, in which:

FIG. 1 is an elevational view of a photovoltaic cell in accordance with a first embodiment of the present invention;

FIG. 2 is an elevational view of a photovoltaic cell in accordance with a second embodiment of the present invention; and

FIG. 3 is an exploded view of a photovoltaic cell in accordance with a third embodiment of the present invention

### DETAILED DESCRIPTION OF THE PREFERRED EMBODIMENT

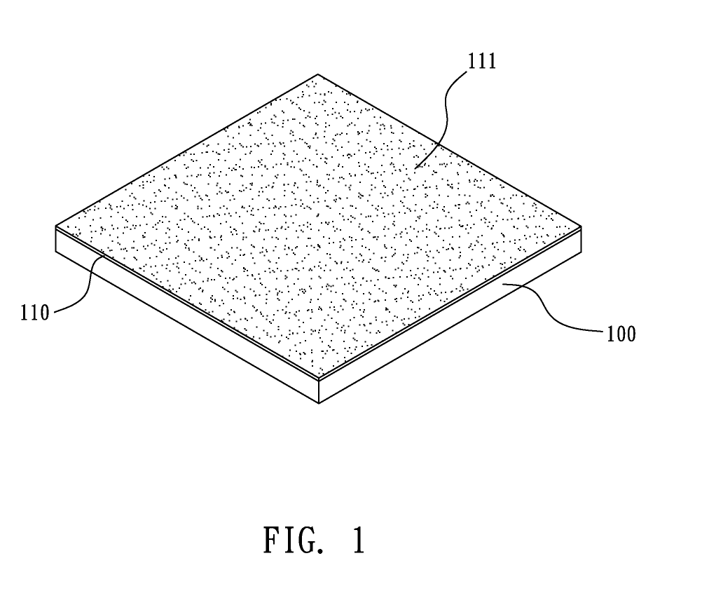

Referring to FIG. 1, a photovoltaic cell in accordance with a first embodiment of the present invention is shown comprising a monocrystalline silicon wafer 100 and a transparent light conversion layer 110.

The monocrystalline silicon wafer 100 is, for example but not limited to, a p-type monocrystalline silicon wafer, a p-type polycrystalline silicon wafer, an n-type monocrystalline silicon wafer, or an n-type polycrystalline silicon wafer. In this embodiment, a p-type monocrystalline silicon wafer is selected as an example for explanation. Also, the present photovoltaic cell is composed of 16-20 silicon wafers no greater than 120 mm, forming a parallel circuit with a total electric resistance less than 100 Ω.

The transparent light conversion layer 110 is made in the form of a thin film having filled therein a transparent phosphor powder 111, for example but not limited to super-dispersion phosphor particle, and kept in contact with the outer surface of the monocrystalline silicon wafer 100 to enhance the absorption of a first specific wavelength range of the solar radiation, for example but not limited to λ<480 nm, and to re-radiate in a second specific wavelength range, for example but not limited to, 500-980 nm, wherein the transparent light conversion layer 110 is an oxygen-containing polymer with polycarbonate, and/or polysiloxanes, and/or acrylatepolymer as its substrate. Furthermore, the polymer has a high transmittance in a wide range of wavelength λ=400˜1200 nm and its addition percentage is 0.1˜50% wt. The transparent light conversion layer 110 may further comprise epoxy (not shown) to enhance its light conversion efficiency.

The chemical composition of the substrate of the phosphor powder 111 is formulated as, for example but not limited to, Me^{II}O.xB₂O₃:EuCePrTbLi, in which Me^{II}=(Mg⁺²,Ca⁺²,Sr⁺²,Ba⁺²), 0.1<x<10, preferably in the range of 0.5<x<2. The basic structure of the phosphor powder 111 is B₂O₃, and the molecule that is bonded to B₂O₃ is formulated as Me^{II}O. These two molecules are neutral molecules. The bonding of these molecules is not subject to the rule of one to one. Therefore, this chemical composition provides a high flexibility for allowing selection of the best processing conditions to achieve better conversion efficiency.

The transparent phosphor powder 111 is further added with Eu, Ce, Pr, Tb and Li. The addition of Eu is, for example but not limited to, 0.1˜15%; Ce is 0˜15%; Pr is 0˜1%; Tb is 0˜1%, and Li is 0.1˜30% by molecule percentage. MgO, CaCO₃, Sr(OH)₂, Ba(OH)₂, H₃BO₃, Eu₂O₃, CeO₂, Pr₂O₁₁, Tb₄O₂, LiOH are selected as raw materials and thoroughly mixed in a proper ratio, and the mixture is then fired in a module with different steps. The first step is to raise the temperature to 500˜700 and remain isothermally for 1 to 3 hours; then in the second step, the temperature is heated up to 1000˜1300 and remains isothermally for 1 to 4 hours. Finally, the material is cooled naturally to become the transparent phosphor powder 111 according to the present invention.

After the photovoltaic cell in accordance with this first embodiment is assembled and exposed to the sunlight, the transparent phosphor powder 111 in the transparent light conversion layer 110 according to the present invention can absorb ultraviolet in the wavelength range λ<480 nm and re-radiate red yellow light in the wavelength range λ=500˜980 nm. The aforementioned absorption and re-radiation can not only reduce the damaging effect of ultraviolet on the monocrystalline silicon wafer 100, but also generate extra electric current and thus enhance the conversion efficiency of the monocrystalline silicon wafer 100 by absorbing the re-radiated red yellow light with the monocrystalline silicon wafer 100. Consequently, the photovoltaic cell according to the first embodiment of the present invention is advantageous over conventional photovoltaic cell assemblies.

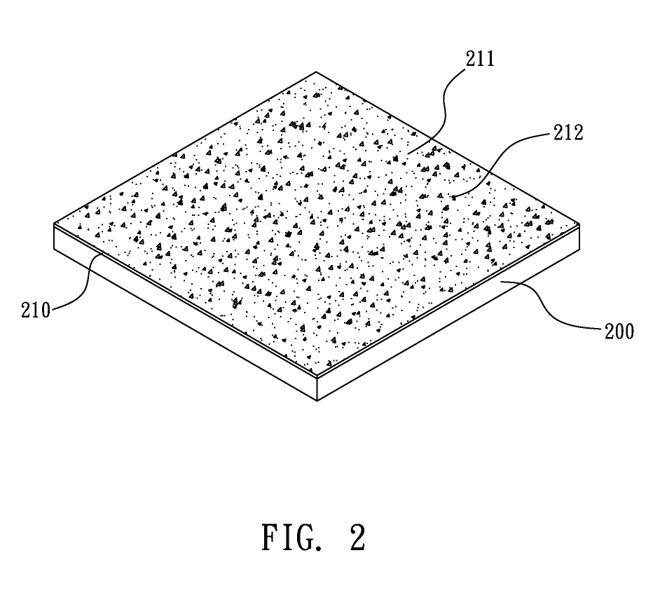

FIG. 2 illustrates a photovoltaic cell in accordance with a second embodiment of the present invention. The photovoltaic cell according to this second embodiment comprises a monocrystalline silicon wafer 200 and a transparent light conversion layer 210.

The monocrystalline silicon wafer 200 is, for example but not limited to, a p-type monocrystalline silicon wafer, a p-type polycrystalline silicon wafer, an n-type monocrystalline silicon wafer, or an n-type polycrystalline silicon wafer. In this embodiment, a p-type monocrystalline silicon wafer is selected as an example for explanation. Also, the present photovoltaic cell is composed of 16-20 silicon wafers no greater than 120 mm, forming a parallel circuit with a total electric resistance less than 100Ω.

The transparent light conversion layer 210 is made by fusing a transparent phosphor powder 211 with a glass material 212, and then bonded to the outer surface of the monocrystalline silicon wafer 200 to enhance the absorption of a first specific wavelength range of the radiation of the sun, for example, but not limited to, λ<480 nm and to re-radiate in a second specific wavelength range, for example, but not limited to, λ=500˜980 nm. The melting point of the transparent phosphor powder 211 is about 1000° C. The melting point of the glass material 212 is also about 1000° C. Therefore, when making a glass for the photovoltaic cell, the transparent phosphor powder 211 can be added to the glass material 212 for fusion. Thus, a glass made according to the present invention contains a transparent phosphor powder therein. Further, the ratio of the transparent phosphor powder 211 in the glass is within the range of 0.1˜75% wt.

The chemical composition of the substrate of the phosphor powder 211 is formulated as, for example but not limited to, Me^{II}O.xB₂O₃:EuCePrTbLi, in which Me^{II}=(Mg⁺²,Ca⁺²,Sr⁺²,Ba⁺²), 0.1<x<10, preferably in the range of 0.5<x<2. The basic structure of the phosphor powder 211 is B₂O₃, and the molecule that is bonded to B₂O₃ is formulated as Me^{II}O. These two molecules are neutral molecules. The bonding of these molecules is not subject to the rule of one to one. Therefore, this chemical composition provides a high flexibility for allowing selection of the best processing conditions to achieve better conversion efficiency.

After the photovoltaic cell in accordance with this second embodiment is assembled and exposed to the sunlight, the transparent phosphor powder 211 in the transparent light conversion layer 210 according to the present invention can absorb ultraviolet in the wavelength range λ<480 nm and re-radiate red yellow light in the wavelength range λ=500˜980 nm. The aforementioned absorption and re-radiation can not only reduce the damaging effect of ultraviolet on the monocrystalline silicon wafer 200, but also generate extra electric current and thus enhance the conversion efficiency of the monocrystalline silicon wafer 200 by absorbing the re-radiated red yellow light with the monocrystalline silicon wafer 200. Consequently, the photovoltaic cell according to this second embodiment of the present invention is advantageous over conventional photovoltaic cell assemblies.

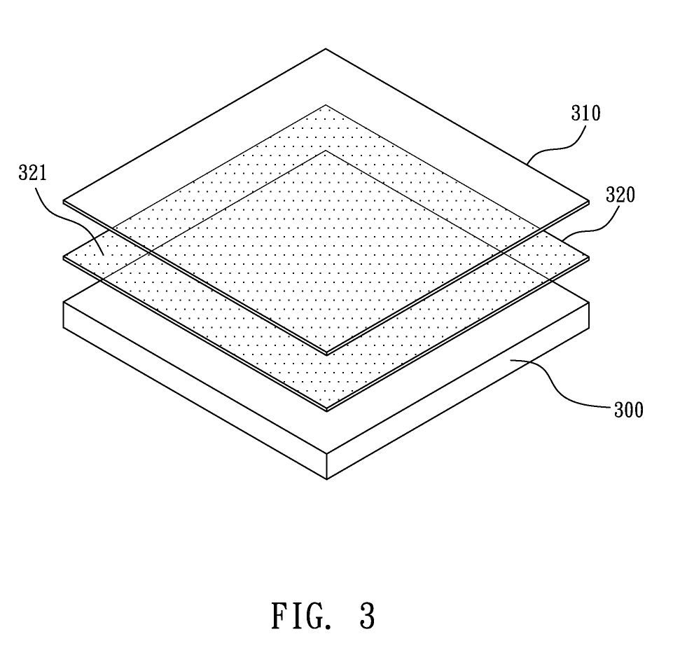

FIG. 3 illustrates a photovoltaic cell in accordance with a third embodiment of the present invention. The photovoltaic cell according to this third embodiment comprises a monocrystalline silicon wafer 300, a glass 310 and a transparent thin layer 320.

The monocrystalline silicon wafer 300 is, for example but not limited to, a p-type monocrystalline silicon wafer, a p-type polycrystalline silicon wafer, an n-type monocrystalline silicon wafer, or an n-type polycrystalline silicon wafer. In this embodiment, a p-type monocrystalline silicon wafer is selected as an example for explanation. Also, the present photovoltaic cell is composed of 16-20 silicon wafers no greater than 120 mm, forming a parallel circuit with a total electric resistance less than 100Ω.

The glass 310 is placed on the outer surface of the monocrystalline silicon wafer 300 to protect the monocrystalline silicon wafer 300. The use of the glass 310 for protection purpose is of the known art and not within the scope of the main features of the present invention, therefore no further detailed description in this regard is necessary.

The transparent thin layer 320 is bonded to the back side of the glass 310. Preferably, the transparent thin layer 320 is made in the form of a thin film having a thickness, for example, but not limited to, about 2 mm. The transparent thin layer 320 has filled therein a transparent phosphor powder 321, and is kept in contact with the outer surface of the monocrystalline silicon wafer 300 to enhance the absorption of a first specific wavelength range of the radiation of the sun, for example, but not limited to, λ<480 nm and to re-radiate in a second specific wavelength range, for example, but not limited to, λ=500˜980 nm. The light transmittance of the transparent thin layer 320 in visible light is >85%. Thus, the transparent phosphor powder 321 used according to the present invention does not cause any masking effect to lower the light conversion efficiency as seen in the application of conventional opaque or low transmittance phosphor powders.

The chemical composition of the substrate of the phosphor powder 321 is formulated as, for example but not limited to, Me^{II}O.xB₂O₃:EuCePrTbLi, in which Me^{II}=(Mg⁺²,Ca⁺²,Sr⁺²,Ba⁺²), 0.1<x<10, preferably in the range of 0.5<x<2. The basic structure of the phosphor powder 321 is B₂O₃, and the molecule that is bonded to B₂O₃ is formulated as Me^{II}O. These two molecules are neutral molecules. The bonding of these molecules is not subject to the rule of one to one. Therefore, this chemical composition provides a high flexibility for allowing selection of the best processing conditions to achieve better conversion efficiency.

After the photovoltaic cell in accordance with this third embodiment is assembled and exposed to the sunlight, the transparent phosphor powder 321 in the transparent thin layer 320 according to this third embodiment of present invention can absorb ultraviolet in the wavelength range λ<480 nm and re-radiate red yellow light in the wavelength range λ=500˜980 nm. The aforementioned absorption and re-radiation can not only reduce the damaging effect of ultraviolet on the monocrystalline silicon wafer 300, but also generate extra electric current and thus enhance the conversion efficiency of the monocrystalline silicon wafer 300 by absorbing the re-radiated red yellow light with the monocrystalline silicon wafer 300. Consequently, the photovoltaic cell according to this third embodiment of the present invention is advantageous over conventional photovoltaic cell assemblies.

Further, the invention also provides a transparent phosphor powder that can absorb the short-wavelength range λ<480 nm and re-radiate it in the wavelength range of λ=500˜980 nm to enhance the absorption of long wavelength radiation for the photovoltaic cell and in turn form more separate p-n electron-hole pairs. Wherein, the transparent phosphor powder is formulated as Me^{II}O.xB₂O₃:EuCePrTbLi, in which Me^{II}=(Mg⁺²,Ca⁺²,Sr⁺²,Ba⁺²), 0.1<x<10, preferably in the range of 0.5<x<2. Furthermore, the transparent phosphor powder is further added with Eu, Ce, Pr, Tb and Li. The addition of Eu is, for example but not limited to, 0.1˜15%; Ce is 0˜15%; Pr is 0˜1%; Tb is 0˜1%, and Li is 0.1˜30% by molecule percentage.

In conclusion, a photovoltaic cell and its transparent phosphor powder can absorb ultraviolet of the sun radiation in the wavelength range λ<480 nm and re-radiate red yellow light in the wavelength range λ=500˜980 nm. Thus, the present invention can not only reduce the damaging effect of ultraviolet on the photovoltaic cell assembly, but also generate red yellow light, which can be absorbed by the photovoltaic cell and in turn generate extra electricity and enhance the conversion efficiency of the photovoltaic cell assembly. Consequently, the present invention can indeed overcome the drawbacks of conventional photovoltaic cell. Furthermore, the basic structure of the transparent phosphor powder in accordance with the present invention is B₂O₃, and the molecule that is bonded to B₂O₃ is formulated as Me^{II}O. These two molecules are neutral molecules. The bonding of these molecules is not subject to the rule of one to one. Thus, this chemical composition provides a high flexibility for allowing selection of the best processing conditions to achieve better conversion efficiency, and therefore the invention effectively eliminates the drawbacks of conventional photovoltaic cells and their transparent light conversion powders.

It is appreciated that although the directional practice device of the present invention is used in a very limited space instead of practicing at the real playing field, effective and steady practice can be obtained as well. Further, it is very easy to set up and to operate the directional practice device of the present invention. These advantages are not possible to achieve with the prior art.

While the invention has been described with reference to the a preferred embodiment thereof, it is to be understood that modifications or variations may be easily made without departing from the spirit of this invention, which is defined by the appended claims.

What is claimed is:

1. A photovoltaic cell, comprising:
a monocrystalline silicon wafer; and
a transparent light conversion layer made in the form of a polymer layer with a transparent phosphor powder filled therein and kept in contact with an outer surface of said monocrystalline silicon wafer to enhance the absorption of the short-wavelength radiation ultraviolet λ<480 nm of the sun and to re-radiate in the wavelength range λ=500˜980 nm, said phosphor powder being formulated as Me^{II}O.xB₂O₃:EuCePrTbLi, in which Me^{II}=(Mg⁺²,Ca⁺², Sr⁺²,Ba⁺²).

2. The photovoltaic cell as claimed in claim 1, wherein said monocrystalline silicon wafer is a p-type monocrystalline silicon wafer, a p-type polycrystalline silicon wafer, an n-type monocrystalline silicon wafer, or an n-type polycrystalline silicon wafer; said transparent phosphor powder is a super-dispersion phosphor particle; said transparent light conversion layer is an oxygen-containing polymer with polycarbonate, and/or polysiloxanes, and/or acrylatepolymer as its substrate, and the polymer has a high transmittance in a wide range of wavelength λ=400˜1200 nm and its addition percentage is 0.1˜50% wt.

3. The photovoltaic cell as claimed in claim 1, wherein said transparent light conversion layer has filled therein epoxy resin.

4. The photovoltaic cell as claimed in claim 1, wherein said transparent phosphor powder has added thereto Eu, Ce, Pr, Tb and Li., and the addition of Eu is 0.1˜15%; Ce is 0˜15%; Pr is 0˜1%; Tb is 0˜1%, and Li is 0.1˜30% by molecule percentage.

5. A photovoltaic cell, comprising:
a monocrystalline silicon wafer; and
a transparent light conversion layer made fusing a transparent phosphor powder with a glass material, and bonded to an outer surface of said monocrystalline silicon wafer to enhance the absorption of a first specific wavelength range of the sun and to re-radiate in a second specific wavelength range, said phosphor powder being formulated as Me^{II}O.xB₂O₃:EuCePrTbLi, in which Me^{II}=(Mg⁺²,Ca⁺², Sr⁺²,Ba⁺²).

6. The photovoltaic cell as claimed in claim 5, wherein said monocrystalline silicon wafer is a p-type monocrystalline silicon wafer, a p-type polycrystalline silicon wafer, an n-type monocrystalline silicon wafer, or an n-type polycrystalline silicon wafer; said first specific wavelength range is λ=480 nm; said second specific wavelength range is λ=500˜980 nm.

7. The photovoltaic cell as claimed in claim 5, wherein said transparent phosphor powder is a super-dispersion phosphor particle, having added thereto Eu, Ce, Pr, Tb and Li., and the addition of Eu is 0.1˜15%; Ce is 0˜15%; Pr is 0˜1%; Tb is 0˜1%, and Li is 0.1˜30% by molecule percentage.

8. The photovoltaic cell as claimed in claim 5, wherein said transparent phosphor powder and said glass material have a common melting point about 1000° C., and the ratio of said transparent phosphor powder in said transparent light conversion layer is 0.1˜75% wt.

9. A photovoltaic cell, comprising:
a monocrystalline silicon wafer;
a glass placed on an outer surface of said monocrystalline silicon wafer; and
a transparent thin layer bonded to a back side of said glass and kept in contact with the outer surface of said monocrystalline silicon wafer to enhance the absorption of the radiation of the sun in a first specific wavelength range and to re-radiate in a second specific wavelength range, said phosphor powder being formulated as Me^{II}O.xB₂O₃:EuCePrTbLi, in which Me^{II}=(Mg⁺²,Ca⁺², Sr⁺²,Ba⁺²).

10. The photovoltaic cell as claimed in claim 9, wherein said monocrystalline silicon wafer is a p-type monocrystalline silicon wafer, a p-type polycrystalline silicon wafer, an n-type monocrystalline silicon wafer, or an n-type polycrystalline silicon wafer; said first specific wavelength range is λ=480 nm; said second specific wavelength range is λ=500˜980 nm; said transparent thin layer has a thickness about 2 mm and a transmittance >85%.

11. The photovoltaic cell as claimed in claim 9, wherein said transparent phosphor powder is a super-dispersion phosphor particle, having added thereto Eu, Ce, Pr, Tb and Li., and the addition of Eu is 0.1˜15%; Ce is 0˜15%; Pr is 0˜1%; Tb is 0˜1%, and Li is 0.1˜30% by molecule percentage.

12. A transparent phosphor powder being to enhance the absorption of the short-wavelength radiation λ<480 nm of the sun and to re-radiate in the wavelength range λ=500˜980 nm, for the photovoltaic cell assembly and in turn form more separate p-n electron-hole pairs, said phosphor powder being formulated as Me^{II}O.xB₂O₃:EuCePrTbLi, in which Me^{II}=(Mg⁺²,Ca⁺², Sr⁺²,Ba⁺²).

13. The transparent phosphor powder as claimed in claim 12, which has added thereto Eu, Ce, Pr, Tb and Li., and the addition of Eu is 0.1˜15%; Ce is 0˜15%; Pr is 0˜1%; Tb is 0˜1%, and Li is 0.1˜30% by molecule percentage.
